(19) United States
(12) Patent Application Publication
(10) Pub. No.: US 2025/0298950 A1
(43) Pub. Date: Sep. 25, 2025

(54) EMULATING A CIRCUIT DESIGN IN COMMUNICATION WITH A PERIPHERAL

(71) Applicant: Xilinx, Inc., San Jose, CA (US)

(72) Inventors: Carsten Hoffmann, Santa Cruz, CA (US); Raghukul Bhushan Dikshit, San Jose, CA (US)

(73) Assignee: Xilinx, Inc., San Jose, CA (US)

(21) Appl. No.: 18/610,340

(22) Filed: Mar. 20, 2024

(51) Int. Cl. G06F 30/331; G06F 30/333

(52) U.S. Cl. CPC G06F 30/331; G06F 30/333

(57) ABSTRACT

Emulating a circuit design in communication with a peripheral includes an emulator including at least a portion of the circuit design. The portion of the circuit design includes a processor circuit and a first bridge circuit coupled to the processor circuit. The first bridge circuit is configured to receive first data from the processor circuit, generate packetized first data from the first data, and convey the packetized first data over a network to a peripheral. The peripheral is remotely located from the emulator and is controlled by signals derived from the packetized first data.

### TECHNICAL FIELD

This disclosure relates to integrated circuits (ICs) and, more particularly, to emulating a circuit design for an IC in communication with a peripheral.

### BACKGROUND

An emulator is a type of data processing system that includes a plurality of constituent, inter-connected integrated circuits (ICs) that provide in-circuit emulation of a circuit design. The circuit design to be emulated is referred to as a “device under test” or “DUT.” The ICs of the emulator may be programmable ICs such as Field Programmable Gate Arrays or “FPGAs,” more complex System-on-Chips (SoCs), or a combination of both. The DUT may be an IC, e.g., a “chip,” being developed or a portion of an IC. The DUT is emulated by synthesizing and mapping components of the DUT to equivalent hardware resources of the constituent ICs of the emulator. In many cases, because the DUT does not fit within a single IC of the emulator, the DUT is partitioned for implementation across multiple ICs of the emulator. For a typical circuit design emulated by an emulator, there may be thousands of nets that cross between ICs of the emulator post-partitioning.

The DUT may be rigorously tested and validated using the emulator before expending more significant resources on fabricating the DUT in silicon. Despite the benefits, emulation technology suffers from several disadvantages. For example, as implemented in an emulator, a DUT typically operates at a clock speed that is significantly slower than had the DUT been fabricated in silicon. This means that running any given test in an emulator will take significantly longer than had such a test been run in a fabricated version of the DUT. Typically, the emulator emulates the DUT at a fraction of the clock frequency that would be used for a silicon implementation of the DUT.

Another disadvantage is the difficulty of testing interoperability of a DUT with a peripheral. As most emulators are enterprise scale systems implemented within a computing rack within a data center or lab environment, the emulators are not easily accessible and, in some cases, may not be physically accessible to the test personnel. This makes connecting a peripheral to a DUT being emulated non-trivial. This also makes positioning test personnel close enough to the emulator to validate transactions between the DUT and the peripheral impractical.

### SUMMARY

In one or more embodiments, a system is disclosed. The system includes an emulator. The emulator includes at least a portion of a circuit design. The portion of the circuit design includes a processor circuit and a bridge circuit coupled to the processor circuit. The bridge circuit is configured to receive first data from the processor circuit, generate packetized first data from the first data, and convey the packetized first data over a network to a peripheral. The peripheral is remotely located from the emulator and is controlled by signals derived from the packetized first data.

The foregoing and other implementations can each optionally include one or more of the following features, alone or in combination. Some example implementations include all the following features in combination.

In some aspects, the peripheral is disposed in a remote system. The remote system also includes a further bridge circuit configured to receive the packetized first data over the network and recover the first data from the packetized first data.

In some aspects, the remote system includes an interface circuit coupled to the further bridge circuit, wherein the interface circuit is configured to convert the first data into signals for conveyance over a physical interface to the peripheral.

In some aspects, the remote system implements another portion of the circuit design that includes the interface circuit.

In some aspects, the circuit design is partitioned at a communication bus interface that couples the processor circuit and an interface circuit for the peripheral within the circuit design.

In some aspects, the circuit design is instrumented to include the bridge circuit.

In some aspects, the peripheral is a secure digital card, a memory, or a universal serial bus device.

In one or more embodiments, a system is disclosed. The system includes an emulator. The emulator includes a first partition of a circuit design. The first partition includes a processor circuit. The emulator includes a first bridge circuit coupled to the processor circuit. The first bridge circuit is configured to receive first data from the processor circuit, generate packetized first data from first data, and convey the packetized first data over a network. The system includes a remote system. The remote system includes a second bridge circuit configured to receive the packetized first data over the network and recover the first data from the packetized first data. The remote system includes a second partition of the circuit design. The second partition includes an interface circuit coupled to the second bridge circuit. The interface circuit is configured to convert the first data into signals for conveyance over a physical interface to a peripheral.

The foregoing and other implementations can each optionally include one or more of the following features, alone or in combination. Some example implementations include all the following features in combination.

In some aspects, the remote system includes a programmable integrated circuit configured to implement the second bridge circuit and the second partition of the circuit design.

In some aspects, the circuit design is partitioned at a communication bus interface that couples the processor circuit and the interface circuit within the circuit design.

In some aspects, the interface circuit is configured to receive second data from the peripheral over the physical interface. The second bridge circuit is configured to generate packetized second data from the second data and convey the packetized second data over the network. The first bridge circuit is configured to receive the packetized second data, recover the second data from the packetized second data, and provide the second data to the processor circuit.

In some aspects, the first partition operates at a first frequency corresponding to the emulator and the second partition operates at a second frequency corresponding to the peripheral. The second frequency is different from the first frequency.

In some aspects, the first frequency is independent of the second frequency.

In some aspects, the circuit design is instrumented to include the first bridge circuit and the second bridge circuit.

In some aspects, the peripheral is a secure digital card, a memory or a universal serial bus device.

In one or more embodiments, a method of emulating a circuit design is disclosed. The method includes generating, by a processor circuit of the circuit design implemented in an emulator, first data. The method includes receiving, by a bridge circuit implemented in the emulator and coupled to the processor circuit, the first data. The method includes generating, by the bridge circuit, packetized first data from the first data. The method includes conveying the packetized first data over a network to a peripheral remotely located from the emulator. The peripheral may be controlled by signals derived from the packetized first data.

The foregoing and other implementations can each optionally include one or more of the following features, alone or in combination. Some example implementations include all the following features in combination.

In some aspects, the method includes partitioning the circuit design into a first partition including the processor circuit and a second partition including an interface circuit for the peripheral. The first partition is implemented in the emulator and the second partition and the peripheral are implemented in a system remotely located from the emulator.

In some aspects, the circuit design is partitioned at a communication bus interface that couples the processor circuit and the interface circuit within the circuit design.

In some aspects, the first partition operates at a first frequency corresponding to the emulator and the second partition operates at a second frequency corresponding to the peripheral. The second frequency is different from the first frequency.

In some aspects, the peripheral is a secure digital card, a memory, or a universal serial bus device.

This Summary section is provided merely to introduce certain concepts and not to identify any key or essential features of the claimed subject matter. Other features of the inventive arrangements will be apparent from the accompanying drawings and from the following detailed description.

### BRIEF DESCRIPTION OF THE DRAWINGS

The inventive arrangements are illustrated by way of example in the accompanying drawings. The drawings, however, should not be construed to be limiting of the inventive arrangements to only the particular implementations shown. Various aspects and advantages will become apparent upon review of the following detailed description and upon reference to the drawings.

FIG. 1 illustrates a system for emulating a circuit design in accordance with one or more embodiments of the disclosed technology.

FIG. 2 is a flow chart illustrating certain operative features of the system of FIG. 1 in accordance with one or more embodiments of the disclosed technology.

FIG. 3 is another flow chart illustrating certain operative features of the system of FIG. 1 in accordance with one or more embodiments of the disclosed technology.

FIG. 4 is another flow chart illustrating certain operative features of the system of FIG. 1 in accordance with one or more embodiments of the disclosed technology.

FIG. 5 illustrates an example implementation of a data processing system for use with the inventive arrangements.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (ICs) and, more particularly, to emulating a circuit design for an IC in communication with a peripheral. In accordance with the inventive arrangements described within this disclosure, methods, systems, and computer program products are provided that are capable of emulating a circuit design and peripheral interoperability. The inventive arrangements may be used in testing and/or validating circuit designs including operability of the circuit design with a selected peripheral.

The inventive arrangements are capable of partitioning the circuit design resulting in multiple partitions. One or more partitions of the circuit design are emulated using an emulator. Another partition of the circuit design that includes circuitry configured to communicate with the peripheral resides in another system remotely located from the emulator. The emulator and the remote system are configured to communicate over a network. The remote system is coupled to a real-world or actual peripheral. As such, the DUT, as emulated, interoperates with the real-world peripheral as opposed to interacting with a software model of the peripheral or an emulated model of the peripheral. In many cases, software and/or emulated models provide idealized behavior that is not representative of the actual or real-world peripheral.

By decoupling certain portions of the circuit design, or DUT, from those that interface with the peripheral, the peripheral may be remotely located from the emulator. This allows certain portions of the circuit design to be emulated in the remote system coupled to the real-world peripheral. The remote system and the real-world peripheral may be disposed at a location or environment that is more conducive for test personnel and/or design personnel to access and observe transactions with the peripheral.

As an illustrative and non-limiting example, one or more first partitions may execute on the emulator while a second partition may be implemented in the remote system. The remote system may be placed or located on the desk of test and/or design personnel. The test personnel need not have access to the lab or data center in which the emulator is located to have physical access to the peripheral. The test personnel may simply access the remote system locally, e.g., in-person. This further allows the test personnel to make changes to the peripheral and/or swap out the peripheral for another without requiring physical access to the emulator or having to ask personnel local to the emulator to perform such tasks.

Decoupling the partitions of the circuit design as described herein also allows each partition to communicate with the other over the network. The decoupled partitions are able to operate at different speeds or clock frequencies. For example, the partition(s) in the emulator are able to operate at the speed of the emulator. The partition implemented in the remote system may operate at a clock frequency of the real-world peripheral, which may be significantly higher than the clock frequency of the emulator. Neither partition is hampered or slowed by operation of the other partition. Unlike other emulation techniques, described herein below, for example, the emulator need not be continually started and stopped. In general, the inventive arrangements only incur latency arising from conveyance of data over the network between the decoupled partitions of the circuit design.

Further aspects of the inventive arrangements are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

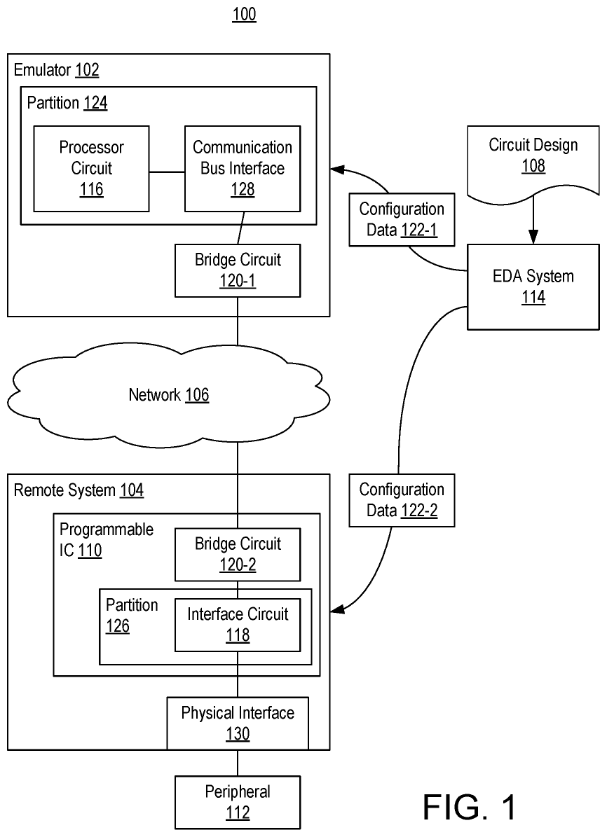

FIG. 1 illustrates a system 100 for emulating a circuit design in accordance with one or more embodiments of the disclosed technology. As illustrated, system 100 includes an emulator 102 and a remote system 104. Emulator 102 and remote system 104 are coupled to a network 106 and are configured to communicate with one another by way of network 106.

An emulator refers to a data processing system that includes a plurality of constituent ICs that provide in-circuit emulation of a circuit design such as circuit design 108. Circuit design 108 is referred to as a “device under test” or “DUT.” The ICs of emulator 102 may be programmable ICs such as Field Programmable Gate Arrays or “FPGAs,” more complex System-on-Chips (SoCs), or a combination of both. Circuit design 108 may be for an IC, e.g., a “chip,” being developed or for a portion of the IC. For purposes of illustration, circuit design 108 may be for a Central Processing Unit (CPU), a Graphics Processing Unit (GPU), an FPGA, an Application-Specific IC, a Digital Signal Processor (DSP), or an SoC. Components of circuit design 108 may be synthesized and mapped to equivalent hardware resources on the ICs of emulator 102. Emulator 102 may include a network adapter (not shown) that allows emulator 102 to couple to network 106.

A network adapter, as included in emulator 102 and/or remote system 104, enables a system to become coupled to one or more other systems, computer systems, remote storage devices, or the like through intervening private or public networks such as network 106. Examples of different network adapters include, but are not limited to, modems, cable modems, Ethernet cards, and transceivers.

Remote system 104 may be implemented as an electronic system having a programmable IC 110 disposed thereon. A programmable IC is an IC that includes at least some programmable circuitry. Programmable logic is a type of programmable circuitry. Examples of programmable ICs may include, but are not limited to, an FPGA, an SoC having at least some programmable circuitry, and/or an ASIC having at least some programmable circuitry.

For purposes of illustration and not limitation, remote system 104 may be implemented as a circuit board, e.g., a card, having programmable IC 110 disposed thereon. The circuit board may be disposed in an enclosure or in another form factor such as a desktop appliance or data processing system. Remote system 104 may include a variety of physical interfaces. For example, remote system 104 may include a network adapter (not shown) that allows remote system 104 to couple to network 106. As illustrated, remote system 104 also couples to a peripheral 112.

In one or more embodiments, peripheral 112 is a device that exists off-chip relative to circuit design 108. For example, peripheral 112 may be a secure digital (SD) card, a Universal Serial Bus (USB) device, an I2C (Inter-Integrated Circuit) device, or other device typically off-chip from the IC to be implemented using circuit design 108.

In one or more other embodiments, peripheral 112 is a device that may be implemented on-chip or as part of circuit design 108. For example, peripheral 112 may represent a subsystem of the circuit design such as a memory, a controller, or the like.

Network 106 may be implemented as or include any combination of the Internet, a mobile network, a Local Area Network (LAN), a Wide Area Network (WAN), a personal area network (PAN), one or more wired networks, one or more wireless networks, or the like. Network 106 may include copper transmission cables, optical transmission fibers, wireless transmission, routers, firewalls, switches, gateway computers and/or edge devices including edge servers. As noted, the various devices and/or systems illustrated in FIG. 1 may include respective network adapters to communicate over network 106. In one or more embodiments, network 106 is implemented as, or includes, a packet-switched network that is configured to convey packetized data.

In the example of FIG. 1, emulator 102 and remote system 104 are located in different locations. For purposes of illustration, emulator 102 may be implemented in a data center while remote system 104 may be located in another room, on another floor of the same building as emulator 102, in a different building than emulator 102, or in an entirely different geographic location (e.g., a different town, city, or state). Appreciably, the only limiting factor in terms of distance between emulator 102 and remote system 104 is the maximum latency incurred by communicating over network 106 that is tolerable to a user (e.g., test personnel).

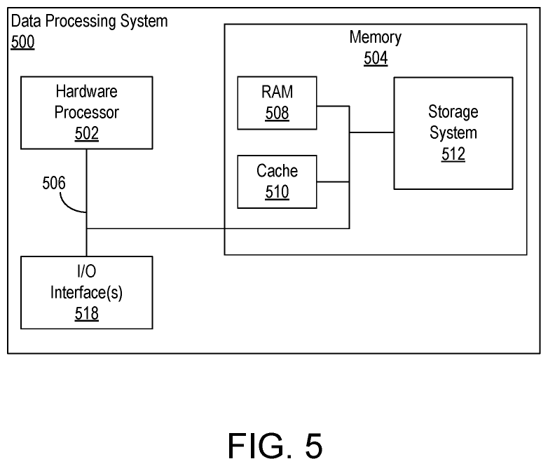

In the example, circuit design 108 is processed using an Electronic Design Automation (EDA) system 114. An example of a data processing system suitable for implementing EDA system 114 is described in connection with FIG. 5. EDA system 114 may be considered separate from system 100 and is shown for purposes of illustration. EDA system 114 may be implemented as a data processing system, e.g., a computer, executing suitable software such as an operating system and software-based circuit design implementation tools (e.g., partitioner, synthesizer, placer, router, etc.). EDA system 114 is capable of partitioning circuit design 108 into two or more different partitions. In one or more embodiments, EDA system 114 partitions circuit design 108 at a boundary defined by a synchronous communication bus that couples a processor circuit 116 of circuit design 108 with an interface circuit 118 of circuit design 108. Interface circuit 118 is a circuit that is configured to communicate with peripheral 112. More particularly, interface circuit 118 is circuitry that is configured to receive instructions and/or transactions from a hardware processor and convert that data into the physical signaling compatible with peripheral 112 and vice versa. EDA system 114 is capable of processing circuit design 108, e.g., as partitioned, through a design flow including stages such as synthesis, placement, routing, and configuration data generation. In general, the portioning performed by EDA system 114 breaks or separates the partitions at a synchronous bus boundary and transforms that boundary into an asynchronous boundary.

An example of a synchronous bus interface is a bus compliant with the Advanced Microcontroller Bus Architecture (AMBA) extensible Interface (AXI) (hereafter “AXI”) protocol. An example of a synchronous communication bus includes a memory-mapped bus such as a memory-mapped AXI bus. AXI defines an embedded microcontroller bus interface for use in establishing on-chip connections between compliant circuit blocks and/or systems. AXI is provided as an illustrative example of a bus interface and is not intended as a limitation of the examples described within this disclosure. It should be appreciated that other similar and/or equivalent protocols, communication buses, bus interfaces, and/or processor buses that are synchronous may be used in lieu of AXI. For example, another type of synchronous communication bus is an AMD Infinity Fabric™ bus available from Advanced Micro Devices, Inc. of Santa Clara, California.

In the example, EDA system 114 is capable of instrumenting circuit design 108 to include or insert bridge circuit 120-1 and bridge circuit 120-2 therein. EDA system 114 couples bridge circuit 120-1 to communication bus interface 128 and connects bridge circuit 120-2 to interface circuit 118. In the example, bridge circuit 120-1 is further coupled to a network adapter (not shown) of emulator 102 while bridge circuit 120-2 is further coupled to a network adapter (not shown) of remote system 104. In general, EDA system 114 partitions and instruments circuit design 108 with circuitry capable of intercepting transactions on the synchronous bus, sending the transactions from emulator 102 over a network, and recreating the transactions in the remote system 104.

EDA system 114 is capable of generating configuration data 122-1 for emulator 102 and configuration data 122-2 for remote system 104. As illustrated, configuration data 122-1 specifies one or more partitions depicted as partition 124. Configuration data 122-1 may also specify bridge circuit 120-1 and any connectivity thereof. Configuration data 122-1 is provided to emulator 102 and loaded into one or more constituent ICs of emulator 102 to implement partition 124 and bridge circuit 120-1 in such constituent IC(s) of emulator 102.

Partition 124, as implemented in emulator 102, includes processor circuit 116 and communication bus interface 128. In the ordinary case where circuit design 108 is implemented in silicon (e.g., not an emulator), communication bus interface 128 couples processor circuit 116 with a synchronous communication bus. As partitioned and instrumented for emulation in accordance with the inventive arrangements, communication bus interface 128 couples processor circuit 116 to bridge circuit 120-1. Within this disclosure, bridge circuit 120-1 is also referred to as the “first bridge circuit.”

Processor circuit 116 may be implemented as a hardware emulation of any of a variety of circuits. For purposes of illustration, processor circuit 116 is an in-circuit emulation, e.g., a hardware emulation implemented in programmable circuitry, of a CPU, a GPU, a DSP, or any type of hardware processor, or portion of such a hardware processor (e.g., one or more cores). Communication bus interface 128 is an interface to a communication bus such as a communication bus as previously described. The communication bus is characterized as a message-based bus. The communication bus also may be characterized as a bus with start and stop functions. Accordingly, processor circuit 116 is capable of sending a message to communication bus interface 128 and continue performing other operations while awaiting a response via communication bus interface 128.

Configuration data 122-2 specifies one or more partitions depicted as partition 126. Configuration data 122-2 may also specify bridge circuit 120-2 and any connectivity thereof. Configuration data 122-2 is provided to remote system 104 and loaded in programmable IC 110 to implement partition 126 and bridge circuit 120-2 therein. Within this disclosure, bridge circuit 120-2 is also referred to as the “second bridge circuit.”

As partitioned and implemented in remote system 104, programmable IC 110 implements partition 126. Partition 126 includes interface circuit 118. As discussed, interface circuit 118 is a portion of circuit design 108 that is decoupled from the portion implemented in emulator 102. Interface circuit 118 may be specified, in some embodiments, as an Intellectual Property (IP) core. As defined herein, the term “Intellectual Property core” or “IP core” means a pre-designed and reusable unit of logic design, a cell, or a portion of chip layout design in the field of electronic circuit design. An IP core may be expressed as a data structure specifying a description of circuitry that performs a particular function. An IP core may be expressed using hardware description language file(s), as a netlist, as a bitstream that programs a programmable IC, or the like. An IP core may be used as a building block within circuit designs adapted for implementation within an IC.

Interface circuit 118 is coupled to bridge circuit 120-2 and to physical interface 130. Physical interface 130 is a physical connector such as a port or a card slot that is capable of coupling remote system 104 to peripheral 112. For example, physical interface 130 may be a USB Port, whether type A, B, or C, an SD card slot, an I2C port, or other type of connector. In one or more embodiments, physical interface 130 may be implemented on an exchangeable or swapable module or daughter card configured to removably connect to remote system 104.

The inventive arrangements depicted in FIG. 1 overcome various disadvantages of conventional emulation technologies. For example, a first conventional emulation technology uses a synthesizable model of the peripheral which may be implemented in the emulator and connect to the DUT also implemented therein. Both the synthesizable model and the DUT are emulated “in-circuit.” This emulation technique, however, suffers from various disadvantages. Both the DUT and the synthesized peripheral model operate at low speeds that maintain the respective clock ratio between the DUT and the peripheral. The peripheral, as emulated, runs at the lower clock frequency of the emulator as opposed to its native clock frequency. Another disadvantage is limited validation fidelity as constrained by the quality of the peripheral model. Further, this emulation technique is not always representative of the “real world” peripheral, which may have bugs or may not accurately or completely follow a given specification.

Another disadvantage of using a synthesizable model of the peripheral is that certain peripherals cannot be fully emulated. For example, an SD card that is gigabytes in size may not be completely emulated since the emulator is often limited in the amount of memory available. Consequently, an SD card that is actually gigabytes in size may be represented by the synthesized model as emulated in the emulator using only a fraction of the total size. That is, the SD card is emulated as having a capacity of megabytes rather than gigabytes. This can be particularly limiting in cases where the SD card, as a peripheral, stores significant program code such as an operating system or other software image from which the DUT is intended to boot.

A second emulation technology uses a virtual model of the peripheral that couples to the emulator using a transactor framework. The virtual model is not synthesizable, but rather is specified in program code that is compiled into executable program code (e.g., object code). The transactor framework is a hardware and software solution that translates between the signaling of the emulator and software transactions utilized by the virtual model of the peripheral. The virtual model may execute on one or more processors of the emulator or on hardware connected to the emulator. This technique has limitations similar to the first emulation technique discussed above with the exception of the memory constraint. Still, with this technique, for every pin toggle from the emulated DUT (e.g., of the interface circuit therein), the emulator stops the clocks of the emulated DUT. When the transactor framework returns with a response, the emulator starts the clocks of the DUT resulting in slow performance.

A third emulation technology uses a speed bridge between the DUT emulated in the emulator and the peripheral. The speed bridge allows the real-world peripheral to be used and communicate with the DUT as emulated. The speed bridge translates low speed traffic from the DUT in the emulator to the high-speed traffic intended for the peripheral interface thereby allowing the DUT as emulated to communicate with the real-world peripheral. Unfortunately, speed bridges have several disadvantages.

Speed bridges suffer from the manageability issues previously discussed in that the speed bridge is directly connected to, and must be located near, the emulator which is typically in a data center. Thus, changing the peripheral (e.g., loading new data onto an SD card or swapping the SD card) requires physical access, which may not be available or may only be available in limited circumstances. Also, since speed bridges are usually placed between the output ports of the interface circuit and the peripheral itself, the speed bridge is protocol aware, which means that a different speed bridge is required for each different type of peripheral (e.g., one for SD cards, another for USB, etc.). Speed bridges also are expensive. The DUT is also continually stopped and started in order to interact with the speed bridge.

The embodiments of FIG. 1 overcome various disadvantage of conventional emulation technologies. For example, the portion of a circuit design that interacts with the peripheral communicates with the real-world peripheral as opposed to a simulacrum thereof. A design or test engineer may be seated in close proximity to remote system 104 to swap out the peripheral for another peripheral (e.g., another SD card including another manufacturer's SD card), adjust or modify the peripheral, monitor the peripheral, etc., in a hands-on manner that is not available using other emulation techniques since physical access to remote system 104 is readily available. Also, peripheral 112 is able to operate at full speed unconstrained by the clock rate of the portion of the DUT in emulator 102.

In one or more embodiments, the decoupling of the portions of the DUT allows a portion of the DUT (e.g., a substantial portion) to run in emulator 102 while peripheral 112 (the real-world peripheral) may sit on an engineer's desktop or benchtop. This is accomplished by splitting circuit design 108 at the communication bus (e.g., communication bus interface 128) between processor circuit 116 and interface circuit 118 and inserting protocol aware bridge circuits 120 therein. Further, the inventive arrangements help to reduce testing overhead and increase design validation fidelity in that real-world peripherals are used in close proximity to test personnel. The inventive arrangements also reduce rebuild time and test iteration time as switching the peripheral type requires only reimplementation of interface circuit 118 implemented in remote system 104. That is, only the IP core needed to communicate with the new peripheral need be processed through a design flow for implementation in remote system 104. Other partitions as emulated in emulator 102 need not be reimplemented.

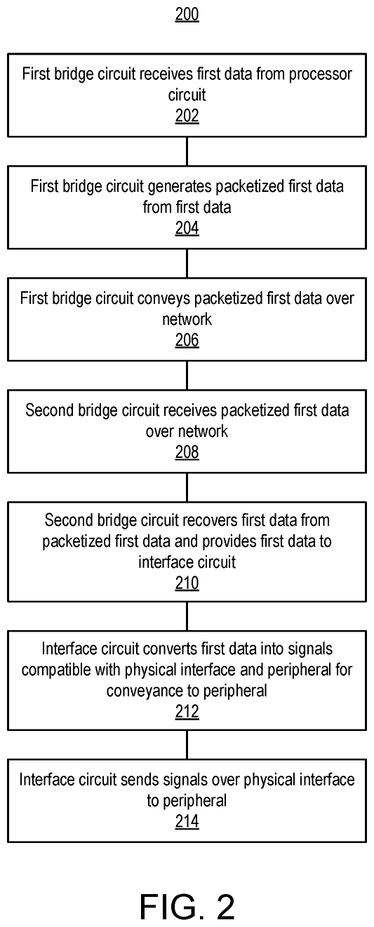

FIG. 2 is a flow chart illustrating certain operative features of system 100 of FIG. 1 in accordance with one or more embodiments of the disclosed technology. Method 200 may begin in a state where processor circuit 116, e.g., a hardware emulation of a hardware processor, initiates a transaction with peripheral 112. Processor circuit 116 may initiate the transaction by sending a message, also referred to herein as “first data,” to communication bus interface 128, which forwards the first data to bridge circuit 120-1. In one or more embodiments, the message is a request to read data or a request to write data.

Referring to FIGS. 1 and 2, in block 202, bridge circuit 120-1 receives the first data from processor circuit 116. In block 204, bridge circuit 120-1 generates packetized first data from the first data. For example, bridge circuit 120-1 is configured to receive the first data formatted as signals compatible with the communication bus and generate a packetized version of the first data for conveyance over network 106.

In block 206, bridge circuit 120-1 conveys the packetized first data over network 106. Bridge circuit 120-1 conveys the packetized first data via network 106 to bridge circuit 120-2.

In block 208, bridge circuit 120-2 receives the packetized first data over network 106. In block 210, bridge circuit 120-2 recovers the first data from the packetized first data and provides the first data to interface circuit 118. In one or more example implementations, interface circuit 118 may be configured to communicate over the communication bus with processor circuit 116. Accordingly, the first data, as recovered and output by bridge circuits 120-2 may be formatted as signaling compatible with the communication bus and provided to interface circuit 118 in such a signaling format.

In block 212, interface circuit 118 converts the first data into signaling compatible with physical interface 130 and peripheral 112 for conveyance to peripheral 112. For example, interface circuit 118 converts the first data into the actual signal(s) output from physical interface 130 to peripheral 112. In this regard, the signals generated and conveyed to peripheral 112 are derived from the packetized first data. As an illustrative and non-limiting example, the first data may be converted by interface circuit 118 into SD card compatible signaling, into USB compatible signaling, I2C compatible signaling, or the like to initiate a read transaction or initiate a write transaction on peripheral 112. In the case of an SD card as the peripheral, the first data is converted into the 5 signals used to interact with an SD card peripheral. Accordingly, in block 214, interface circuit 118 sends the signals over physical interface 130 to peripheral 112.

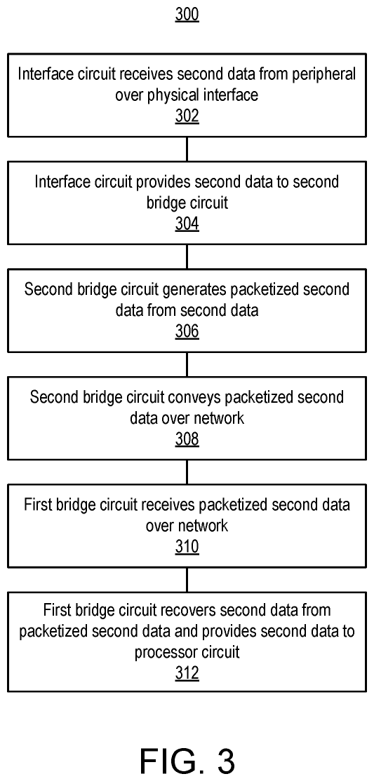

FIG. 3 is another flow chart illustrating certain operative features of system 100 of FIG. 1 in accordance with one or more embodiments of the disclosed technology. Method 300 may begin where operations as described in connection with FIG. 2 have been performed and a response, referred to herein as “second data” is to be provided from peripheral 112 to processor circuit 116.

Referring to FIGS. 1 and 3, in block 302, interface circuit 118 receives second data from peripheral 112 over physical interface 130. The second data may be initially specified using the signaling compatible with physical interface 130 and peripheral 112. In block 304, interface circuit 118 provides the second data to bridge circuit 120-2. For example, interface circuit 118 is capable of converting the second data from the signaling compatible with peripheral 112 into another format or signaling that is compatible with the communication bus. Interface circuit 118 may provide the second data to bridge circuit 120-2 in that format.

In block 306, bridge circuit 120-2 generates packetized second data from the second data. In block 308, bridge circuit 120-2 conveys the packetized second data over network 106. In block 310, bridge circuit 120-1 receives the packetized second data over network 106. In block 312, bridge circuit 120-1 recovers the second data from the packetized second data and provides the second data to processor circuit 116. For example, in block 312, bridge circuit 120-1 formats the second data into signaling that is compatible with the communication bus and outputs the second data to communication bus interface 128, which provides the second data to processor circuit 116.

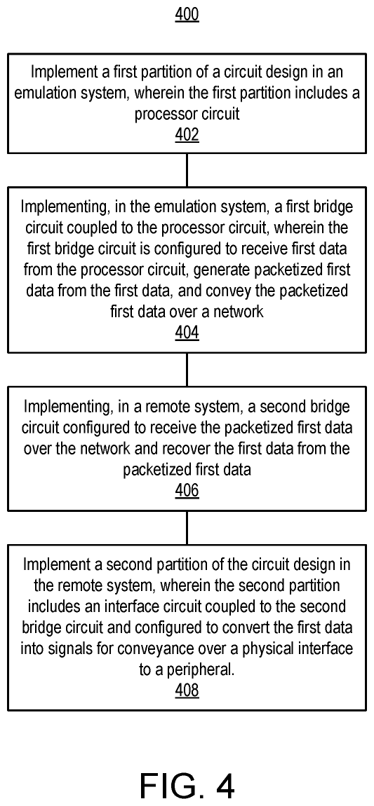

FIG. 4 is another flow chart illustrating certain operative features of system 100 of FIG. 1 in accordance with one or more embodiments of the disclosed technology. Referring to FIGS. 1 and 4, in block 402, a first partition (e.g., partition 124) of circuit design 108 is implemented in emulator 102. The first partition includes processor circuit 116. In block 404, a first bridge circuit (e.g., bridge circuit 120-1) is implemented in emulator 102. The first bridge circuit is coupled to processor circuit 116. The first bridge circuit is configured to receive first data from processor circuit 116, generate packetized first data from the first data, and convey the packetized first data over network 106.

In block 406, a second bridge circuit (e.g., bridge circuit 120-2) is implemented in remote system 104. The second bridge circuit is configured to receive the packetized first data over network 106 and recover the first data from the packetized first data. In block 408, a second partition (e.g., partition 126) of circuit design 108 is implemented in remote system 104. The second partition includes interface circuit 118 coupled to the second bridge circuit. Interface circuit 118 is configured to convert the first data into signals for conveyance over physical interface 130 to peripheral 112.

In one or more embodiments, peripheral 112 is implemented as a secure digital card. In one or more embodiments, peripheral 112 is a memory. In one or more embodiments, peripheral 112 is a USB device. Other examples of peripheral 112 may include, but are not limited to, Serial Peripheral Interface (SPI) compatible devices, Quad-SPI (QSPI) compatible devices, NAND flash devices, NvRAM devices, Solid State Drives (SSDs), hard disk drives (HDDs), and Double Data Rate (DDR) memory devices.

In one aspect, method 400 includes partitioning circuit design 108 into the first partition and the second partition. Circuit design 108 may be partitioned at a communication bus interface for a synchronous communication bus (e.g., communication bus interface 128) by EDA system 114. As noted, the communication bus interface couples processor circuit 116 and interface circuit 118 and, as such, defines a point or boundary in circuit design 108 for partitioning.

In another aspect, interface circuit 118 is configured to receive second data from peripheral 112 over physical interface 130. The second bridge circuit is configured to generate packetized second data from the second data and convey the packetized second data over network 106. The first bridge circuit is configured to receive the packetized second data, recover the second data from the packetized second data, and provide the second data to processor circuit 116.

In another aspect, the first partition (e.g., partition 124) operates at a first frequency corresponding to emulator 102 and the second partition (e.g., partition 126) operates at a second frequency corresponding to peripheral 112. The second frequency is different from the first frequency. A technical effect is that partition 126 and peripheral 112 are able to operate at a higher clock frequency than had the second partition been implemented in emulator 102 or implemented as an executable model (e.g., a C/C++ type of model executed by a data processing system). The first frequency is independent of the second frequency. In consequence, processor circuit 116 need not be continually started and stopped while waiting for a response from peripheral 112.

In another aspect, as discussed, circuit design 108 is instrumented to include the first bridge circuit and the second bridge circuit.

An example of a data processing system that is capable of performing the operations described within this disclosure (e.g., FIG. 1) is described in connection with FIG. 5.

FIG. 5 illustrates an example implementation of a data processing system 500. Data processing system 500 can include a hardware processor 502, a memory 504, and a bus 506 that couples various system components including memory 504 to hardware processor 502.

Hardware processor 502 may be implemented as one or more hardware processors. In an example, hardware processor 502 is implemented as a central processing unit (CPU). Hardware processor 502 may be implemented using a complex instruction set computer architecture (CISC), a reduced instruction set computer architecture (RISC), a vector processing architecture, or other known architectures. Example processors include, but are not limited to, processors having an x86 type of architecture (IA-32, IA-64, etc.), Power Architecture, ARM processors, and the like.

Bus 506 represents one or more of any of a variety of communication bus structures. By way of example, and not limitation, bus 506 may be implemented as a Peripheral Component Interconnect Express (PCIe) bus. Data processing system 500 typically includes a variety of computer system readable media. Such media may include computer-readable volatile and non-volatile media and computer-readable removable and non-removable media.

Memory 504 can include computer-readable media in the form of volatile memory, such as random-access memory (RAM) 508 and/or cache memory 510. Data processing system 500 also can include other removable/non-removable, volatile/non-volatile computer storage media. By way of example, storage system 512 can be provided for reading from and writing to a non-removable, non-volatile magnetic and/or solid-state media (not shown and typically called a “hard drive”), which may be included in storage system 512. Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 506 by one or more data media interfaces. Memory 504 is an example of at least one computer program product.

Memory 504 is capable of storing computer-readable program instructions that are executable by hardware processor 502. For example, the computer-readable program instructions can include an operating system, one or more application programs, other program code, and program data. In one or more embodiments, the computer-readable instructions include software-based circuit design implementation tools as previously described.

Hardware processor 502, in executing the computer-readable program instructions, is capable of performing the various operations described herein that are attributable to a computer. It should be appreciated that data items used, generated, and/or operated upon by data processing system 500 are functional data structures that impart functionality when employed by data processing system 500. As defined within this disclosure, the term “data structure” means a physical implementation of a data model's organization of data within a physical memory. As such, a data structure is formed of specific electrical or magnetic structural elements in a memory. A data structure imposes physical organization on the data stored in the memory as used by an application program executed using a processor.

Data processing system 500 may include one or more Input/Output (I/O) interfaces 518 communicatively linked to bus 506. I/O interface(s) 518 allow data processing system 500 to communicate with one or more external devices and/or communicate over one or more networks such as a local area network (LAN), a wide area network (WAN), and/or a public network (e.g., the Internet). Examples of I/O interfaces 518 may include, but are not limited to, network cards, modems, network adapters, hardware controllers, etc. Examples of external devices also may include devices that allow a user to interact with data processing system 500 (e.g., a display, a keyboard, and/or a pointing device) and/or other devices such as accelerator card or the other systems described herein (e.g., emulator 102 and/or remote system 104).

Data processing system 500 is only one example implementation. Data processing system 500 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

The example of FIG. 5 is not intended to suggest any limitation as to the scope of use or functionality of example implementations described herein. Data processing system 500 is an example of computer hardware that is capable of performing the various operations described within this disclosure. In this regard, data processing system 500 may include fewer components than shown or additional components not illustrated in FIG. 5 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular embodiments only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the term “approximately” means nearly correct or exact, close in value or amount but not precise. For example, the term “approximately” may mean that the recited characteristic, parameter, or value is within a predetermined amount of the exact characteristic, parameter, or value.

As defined herein, the terms “at least one,” “one or more,” and “and/or,” are open-ended expressions that are both conjunctive and disjunctive in operation unless explicitly stated otherwise. For example, each of the expressions “at least one of A, B, and C,” “at least one of A, B, or C,” “one or more of A, B, and C,” “one or more of A, B, or C,” and “A, B, and/or C” means A alone, B alone, C alone, A and B together, A and C together, B and C together, or A, B and C together.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of computer-readable storage media. A non-exhaustive list of examples of computer-readable storage media include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a portable compact disc read-only memory (CD-ROM), a digital versatile disk (DVD), a memory stick, a floppy disk, or the like.

As defined herein, “data processing system” means one or more hardware systems configured to process data, each hardware system including at least one hardware processor programmed to initiate operations and memory.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context.

As defined herein, the term “responsive to” and similar language as described above, e.g., “if,” “when,” or “upon,” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the terms “individual,” “user,” and “personnel” each refer to a human being or a plurality of human beings depending on the context.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the terms “one embodiment,” “an embodiment,” “in one or more embodiments,” “in particular embodiments,” or similar language mean that a particular feature, structure, or characteristic described in connection with the embodiment is included in at least one embodiment described within this disclosure. Thus, appearances of the aforementioned phrases and/or similar language throughout this disclosure may, but do not necessarily, all refer to the same embodiment.

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or media) having computer-readable program instructions thereon for causing a processor to carry out aspects of the inventive arrangements described herein. Within this disclosure, the term “program code” is used interchangeably with the term “program instructions.” Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Computer-readable program instructions may include state-setting data. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the computer-readable program instructions by utilizing state information of the computer-readable program instructions to personalize the electronic circuitry, in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by computer-readable program instructions, e.g., program code.

These computer-readable program instructions may be provided to a processor of a computer, special-purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the operations specified in the flowchart and/or block diagram block or blocks.

The computer-readable program instructions may also be loaded onto a computer, other programmable data processing apparatus, or other device to cause a series of operations to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more executable instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

The descriptions of the various embodiments of the disclosed technology have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system, comprising:
an emulator including:
at least a portion of a circuit design, wherein the portion of the circuit design includes a processor circuit; and
a bridge circuit coupled to the processor circuit, wherein the bridge circuit is configured to receive first data from the processor circuit, generate packetized first data from the first data, and convey the packetized first data over a network to a peripheral;
wherein the peripheral is remotely located from the emulator and is controlled by signals derived from the packetized first data.

2. The system of claim 1, wherein the peripheral is disposed in a remote system and the remote system includes a further bridge circuit configured to receive the packetized first data over the network and recover the first data from the packetized first data.

3. The system of claim 2, wherein the remote system includes an interface circuit coupled to the further bridge circuit, wherein the interface circuit is configured to convert the first data into signals for conveyance over a physical interface to the peripheral.

4. The system of claim 3, wherein the remote system implements another portion of the circuit design that includes the interface circuit.

5. The system of claim 1, wherein the circuit design is partitioned at a communication bus interface that couples the processor circuit and an interface circuit for the peripheral within the circuit design.

6. The system of claim 1, wherein the circuit design is instrumented to include the bridge circuit.

7. The system of claim 1, wherein the peripheral is a secure digital card, a memory, or a universal serial bus device.

8. A system, comprising:
an emulator including:
a first partition of a circuit design, wherein the first partition includes a processor circuit; and
a first bridge circuit coupled to the processor circuit, wherein the first bridge circuit is configured to receive first data from the processor circuit, generate packetized first data from the first data, and convey the packetized first data over a network; and
a remote system including:
a second bridge circuit configured to receive the packetized first data over the network and recover the first data from the packetized first data; and
a second partition of the circuit design, wherein the second partition includes an interface circuit coupled to the second bridge circuit and configured to convert the first data into signals for conveyance over a physical interface to a peripheral.

9. The system of claim 8, wherein the remote system comprises a programmable integrated circuit configured to implement the second bridge circuit and the second partition of the circuit design.

10. The system of claim 8, wherein the circuit design is partitioned at a communication bus interface that couples the processor circuit and the interface circuit within the circuit design.

11. The system of claim 8, wherein:
the interface circuit is configured to receive second data from the peripheral over the physical interface;
the second bridge circuit is configured to generate packetized second data from the second data and convey the packetized second data over the network; and
the first bridge circuit is configured to receive the packetized second data, recover the second data from the packetized second data, and provide the second data to the processor circuit.

12. The system of claim 8, wherein the first partition operates at a first frequency corresponding to the emulator and the second partition operates at a second frequency corresponding to the peripheral, and wherein the second frequency is different from the first frequency.

13. The system of claim 12, wherein the first frequency is independent of the second frequency.

14. The system of claim 8, wherein the circuit design is instrumented to include the first bridge circuit and the second bridge circuit.

15. The system of claim 8, wherein the peripheral is a secure digital card, a memory, or a universal serial bus device.

16. A method of emulating a circuit design, the method comprising:
generating, by a processor circuit of the circuit design implemented in an emulator, first data;
receiving, by a bridge circuit implemented in the emulator and coupled to the processor circuit, the first data;
generating, by the bridge circuit, packetized first data from the first data; and
conveying the packetized first data over a network to a peripheral remotely located from the emulator;
wherein the peripheral is controlled by signals derived from the packetized first data.

17. The method of claim 16, further comprising:
partitioning the circuit design into a first partition including the processor circuit and a second partition including an interface circuit for the peripheral;
wherein the first partition is implemented in the emulator and the second partition and the peripheral are implemented in a system remotely located from the emulator.

18. The method of claim 17, wherein the circuit design is partitioned at a communication bus interface that couples the processor circuit and the interface circuit within the circuit design.

19. The method of claim 17, wherein the first partition operates at a first frequency corresponding to the emulator and the second partition operates at a second frequency corresponding to the peripheral, and wherein the second frequency is different from the first frequency.

20. The method of claim 16, wherein the peripheral is a secure digital card, a memory, or a universal serial bus device.
